(19) United States
(12) Patent Application Publication
(10) Pub. No.: US 2006/0164909 A1
(43) Pub. Date: Jul. 27, 2006

(54) System, method and storage medium for providing programmable delay chains for a memory system

(75) Inventors: Kevin C. Gower, LaGrangeville, NY (US); Kirk D. Lamb, Kingston, NY (US); Dustin J. VanStee, Poughkeepsie, NY (US)

Correspondence Address: Philmore H. Colburn II;Cantor Colburn LLP, 55 Griffin Road South, Bloomfield, CT, 06002, US

(73) Assignee: International Business Machines Corporation, Armonk, NY (US)

(21) Appl. No.: 11/041,335

(22) Filed: Jan. 24, 2005

(51) Int. Cl. G11C 8/00

(52) U.S. Cl. 365/233

(57) ABSTRACT

A memory system including a plurality of delay lines and a processor in communication with the delay lines. The delay lines are in communication with a bus attached to a memory device. The bus includes a plurality of wires and each of the delay lines corresponds to on of the plurality of wires. The processor receives a plurality of data bits and a data strobe via the wires on the bus. Each of the data bits includes data eye. The process also automatically calibrates the target data eye of each of the data bits and corresponds to the target data eye. In addition, the processor centers the data strobe over the target data eye.

### BACKGROUND OF THE INVENTION

The invention relates to a memory system and, in particular, to providing programmable delay chains for a memory system.

In a memory system, a group of data bits are often grouped together and read (or written) at the same time via a data strobe, or clock. Each data bit has a “data eye”, which as used herein refers to a measure of timing for a single bit. The data eye is the width (in time) of the earliest time that a valid value can be sampled to the latest time that a value can be sampled at a receiver without data corruption. As used herein, the term “overlapping data eye” refers to the grouping together of a bus of single bits, and measuring the width (in time) of the earliest time that a valid bus value can be sampled to the latest time that a bus value can be sampled at a receiver without data corruption.

Skew, or variability in arrival times, of single data bit can cause the data eye to be smaller for individual data bits, and as a result, the overlapping data eye becomes smaller. There are many sources of skew in a memory system. When performing a write to memory, sources of skew may include: launching clock skew; skew due to silicon and wiring before leaving a memory interface device (MID) such as an application specific interface circuit (ASIC); skew due to card wire imbalance; and skew in the memory device (e.g., a dynamic random access memory “DRAM”). During a read to memory, sources of skew may include: skew across the memory device driver logic and clock distribution; skew due to card wire imbalance; skew due to silicon and wiring before arriving at a memory device interface device capture latch; and data strobe clock distribution skew.

As bus frequencies within memory systems increase, the overlapping data eye at the memory device and memory interface device gets smaller due to the skew, noise, and clock jitter relative to the clock period. This results in a smaller time frame in which data must be captured in order to ensure that the data is valid. Solutions, such as the use of timing analysis and card wire balancing techniques, to reduce the data skew and improve the data eye at the memory device and memory interface device have been employed. One problem with these approaches is that the data eye for writes and reads to the memory device is very dependent on how good the wiring is between the memory interface device and the memory device.

An alternate method of increasing the overlapping data eye is to utilize delay circuits. Currently this involves a manual configuration of the delay circuits via a timing analysis or measurement. Calibration by the use of system timing analysis may be utilized to calculate the delays for each bit in the write and read paths. This information (generally compiled in a spreadsheet) is then used to figure out the arrival of the data bits and data strobe. The system timer would then program delay elements for each bit to perform per bit de-skew (PBD) and data strobe centering (DSC). Advantages of this approach include the ability to perform the programming of the delay elements before the hardware is actually tested in a laboratory environment with new information from laboratory testing being fed back into the spreadsheet. Disadvantages to this approach include that all process voltage temperature (PVT) settings must be taken into account and a setting that works under all conditions must be selected. This setting may be sub-optimal for some of the memory devices. Another drawback is that delay information must be modeled accurately for this approach to work.

Another approach to increasing the overlapping data eye is calibration through measurement. Using this approach, an engineer would set up a scope loop such that the data bit arrivals and data strobe arrivals could be measured at both the memory device and the memory interface device. Using the arrival time information, the memory interface device can be programmed to eliminate skew. Disadvantages to this approach include: it is sensitive to process voltage temperature (PVT) drift (where PVT drift is the variation in signal arrival times due to the fact that process/voltage/temperature cause the speed at which signals propagate to change); that it is manual and therefore it takes a long time to perform the task; and that the measurement equipment must be extremely accurate.

### BRIEF SUMMARY OF THE INVENTION

Exemplary embodiments of the present invention include a memory system with a plurality of delay lines and a processor in communication with the delay lines. The delay lines are in communication with a bus attached to a memory device. The bus includes a plurality of wires and each of the delay lines corresponds to one of the plurality of wires. Each of the data bits includes a data eye. The processor also automatically calibrates a target data eye for the data bits and adjusts the delay lines so that the data eye of each of the data bits corresponds to the target data eye. In addition, the processor centers the data strobe over the target data eye.

Additional exemplary embodiments of include a method for providing programmable delay chains in a memory system. The method includes receiving a plurality of data bits and a data strobe via wires on a bus. Each of the data bits includes a data eye. The memory system includes a plurality of delay lines in communication with the wires on the bus. The method further includes automatically calibrating a target data eye for the data bits and adjusting the delay lines. The delay lines are adjusted so that the data eye of each of the data bits corresponds to the target data eye. In addition, the method includes centering the data strobe over the target data eye.

Further exemplary embodiments include a storage medium for providing programmable delay chains in a memory subsystem. The storage medium is encoded with machine readable computer program code for causing a computer to implement a method. The method includes receiving a plurality of data bits and a data strobe via wires on a bus. Each of the data bits includes a data eye. The memory system includes a plurality of delay lines in communication with the wires on the bus. The method further includes automatically calibrating a target data eye for the data bits and adjusting the delay lines. The delay lines are adjusted so that the data eye of each of the data bits corresponds to the target data eye. In addition, the method includes centering the data strobe over the target data eye.

### BRIEF DESCRIPTION OF THE DRAWINGS

Referring now to the drawings wherein like elements are numbered alike in the several FIGURES:

FIG. 1 depicts an exemplary data and data strobe timing diagram;

FIG. 2 depicts an exemplary data and data strobe timing diagram that includes error terms added;

FIG. 3 depicts a data and data strobe diagram that includes corrected error terms in accordance with exemplary embodiments of the present invention;

FIG. 4 depicts a high level system diagram of a system that may be utilized by exemplary embodiments of the present invention;

FIG. 5 depicts a delay line and circuit diagram that may be utilized by exemplary embodiments of the present invention;

FIG. 6 depicts a process flow diagram for correcting error terms in accordance with exemplary embodiments of the present invention; and

FIG. 7 depicts a hardware assisted calibration block diagram that may be implemented to correct error terms in accordance with exemplary embodiments of the present invention.

### DETAILED DESCRIPTION OF THE PREFERRED EMBODIMENTS

Exemplary embodiments of the present invention include a memory system that utilizes programmable delay lines to capture data at high frequencies. Delay lines for individual data signals are programmed to values that provide for a larger valid overlapping data eye by lining up a group of data signals that correspond to the same strobe signal with the latest arriving data signal in the group. The memory system includes a memory device in communication with a memory interface device (MID). There are two main calibrations procedures that occur: calibration of the write data bus to satisfy the DRAM write timing requirements; and calibration of the read data capture logic within the MID such that read data is correctly sampled. Utilizing exemplary embodiments of the present invention may result in an increased overlapping data eye and may improve bus turn around time. As used herein, the term “bus turn around time” refers to the time that it takes for one device (e.g., a memory device and a memory interface device) to stop driving the bus and another device to start driving the bus.

Exemplary embodiments of the present invention utilize programmable delay lines to assist in the launching and capturing of data, and to reduce skew across a bus of data bits and the clock that is sampling the data bits (i.e., the data strobe). In general, many programmable delay elements may be utilized to delay a signal. The more elements used, the greater the amount of per bit delay that may be added. The skew can be reduced to the amount of delay provided by the finest delay setting plus jitter for a certain process, voltage, and temperature setting.

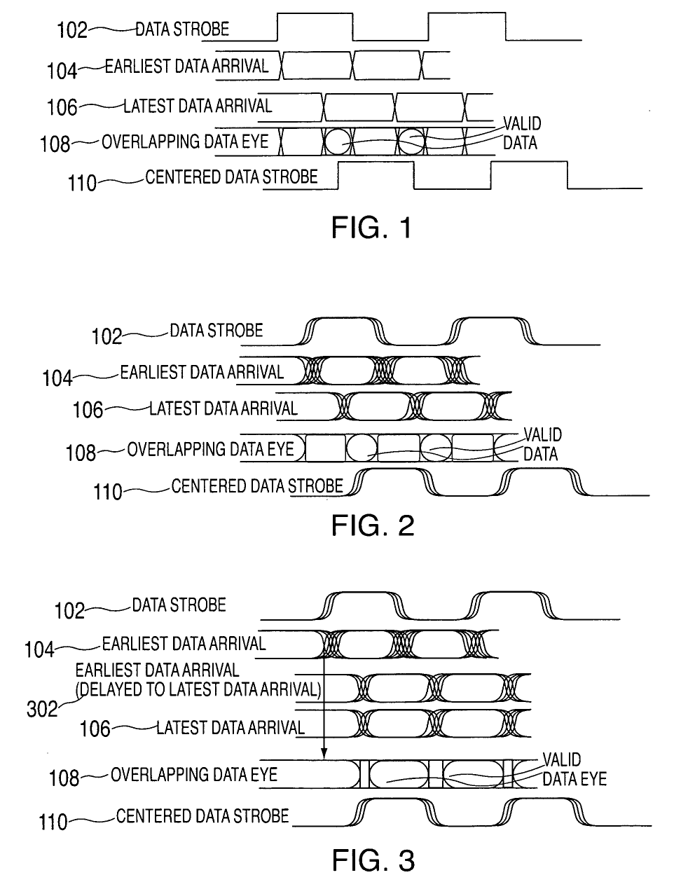

FIG. 1 depicts an exemplary data and data strobe timing diagram. The data strobe 102 from a memory device is depicted along with an earliest data arrival bit 104 and a latest data arrival bit 106 from the memory device. Because the earliest data arrival bit 104 and the latest data arrival bit 106 are both clocked, or strobed, by the same data strobe 102, the overlapping data eye 108 includes the time frame when the earliest data arrival bit 104 and latest data arrival bit 106 may both be sampled. The centered data strobe 110 is moved to this time frame where data is valid on both the rising and falling edge to support a double data rate (DDR) implementation. The timing diagram depicted in FIG. 1 does not include the impact of any error terms.

FIG. 2 depicts an exemplary data and data strobe timing diagram that includes error terms. FIG. 2 includes the same input as FIG. 1 with error terms such as noise and skew added to the diagram. The result is that the arrival times of the data strobe 102, earliest data arrival bit 104 and latest data arrival bit 106 cannot be predicted as precisely as they could in FIG. 1. As a result, the overlapping data eye 108 where sampling may occur becomes smaller. Further, the centered data strobe 110 includes variability so that the overlapping data eye 108 becomes even smaller.

FIG. 3 depicts an exemplary data and data strobe diagram that includes corrected error terms in accordance with exemplary embodiments of the present invention. The earliest data arrival bit 104 (along with all other data bits to be strobed by the data strobe 102) is delayed to be received at the same time as the latest data arrival bit 106 resulting in the earliest data arrival bit delayed to coincide with the latest data arrival bit 302. As depicted in FIG. 3, this results in a larger overlapping data eye 108. This process of delaying data bits to arrive with the latest data arrival bit 302 is referred to as per bit de-skew (PBD). In addition, the data strobe 102 is delayed to be centered over the overlapping data eye 108, resulting in the centered data strobe 110. This process of centering the data strobe 102 is referred to as data strobe centering (DSC). To perform the DSC, the bits must have already gone through the PBD. During a write, the PBD and DSC occur at the memory device I/O 402. During a read, the PBD and DSC occur either at the memory interface device 404 or at the internal sampling latch in the memory interface device. Performing the PBD and DSC at the sampling latch may be preferable because it takes into account the possible differences in silicon delay relative to the data and data strobe bits internal to the memory interface device. As described herein, the processes of PBD and DSC are automated and may be performed by hardware circuitry and/or software instructions. In addition, exemplary embodiments of the present invention may be utilized with any number of data bits being strobed by a data strobe.

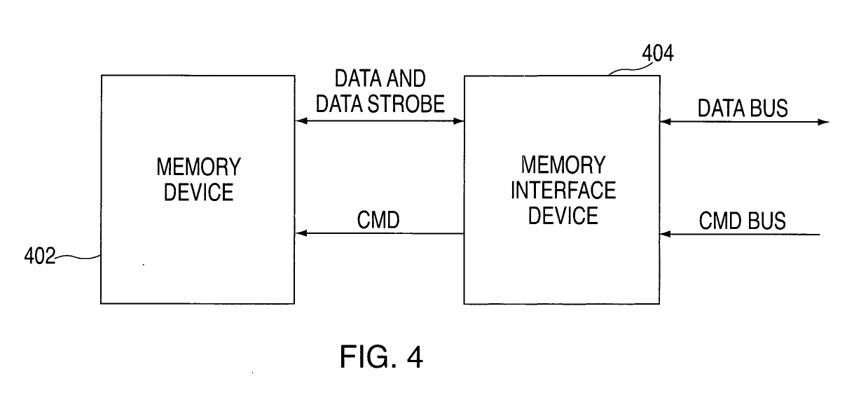

FIG. 4 depicts a high level system diagram of a system that may be utilized by exemplary embodiments of the present invention. At the system level, as depicted in FIG. 4, there is a MID 404 that interfaces to a memory device 402 (e.g., a DRAM). Between the MID 404 and the memory device 402, there is a command and data bus. The command bus is utilized to send memory device commands from the MID 404 to the memory device 402. The data bus is used by the MID 404 to send data to the memory device 402 and to receive data from the memory device 402. Included in the data is the data clock, or data strobe 102. The MID 404 communicates with the data bus (both input and output) and command bus in the memory system. In an exemplary embodiment of the present invention, the software and/or circuitry to calculate and implement the programmable delay is included in the MID 404. (Just a note here that the picture shows that the data busses are bi-directional, however busses could be uni-directional.)

In the memory interface calibration utilized by exemplary embodiments of the present invention, delay lines are used to allow the MID 404 to safely send and capture data, and also to control the owner of the bus. Since the memory device is a “dumb” device in terms of receiving and launching data, all the de-skew logic is in the MID 404. During a write, the outgoing data bits are de-skewed, the outgoing data strobe is centered in the data eye, and the MID 404 drives the bus for an amount of time sufficient for the memory device 402 to capture the data on the bus. During read, the received data bits are de-skewed again, the data strobe is centered within the data eye once again, and the receiver is enabled to effectively sample the data at the correct time. Also, during writes and reads, the I/O's dynamic terminator is turned off relative to the data on the bus to create the proper signaling environment.

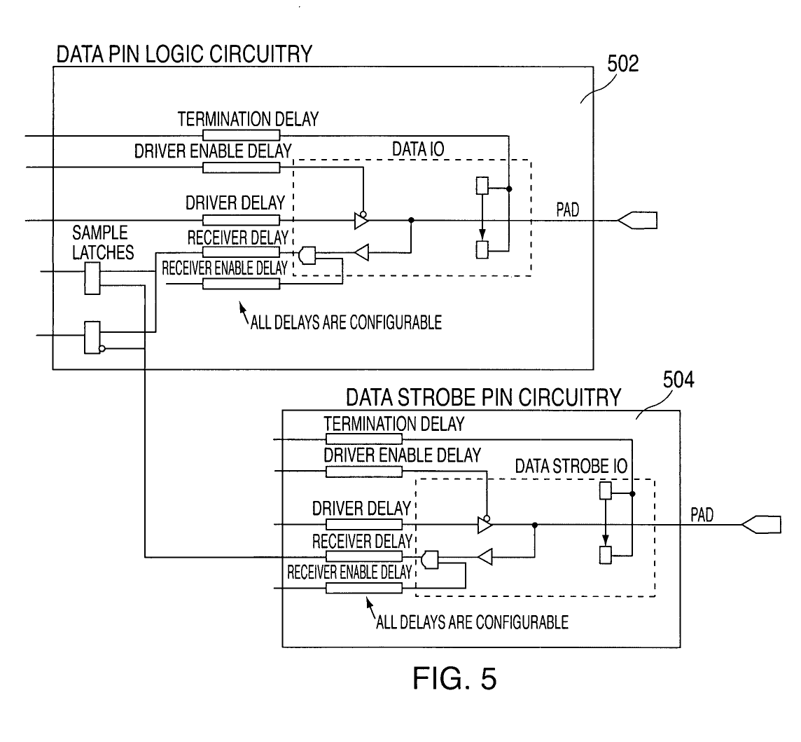

FIG. 5 depicts a delay line and circuit diagram that may be utilized by exemplary embodiments of the present invention. FIG. 5 includes data pin logic circuitry 502 circuitry for implementing a programmable delay, with each data bit being transferred between the MID 404 and the memory device 402 having its own set of data pin logic circuitry 502. The data pin logic circuitry 502 is utilized to perform the PBD to create a larger overlapping data eye 108. In addition, FIG. 5 includes data strobe pin logic circuitry 504 for centering the data strobe 102 over the overlapping data eye 108 that is formed by the set of data bits that are strobed as a group. All of the boxes in FIG. 5 that specify “delay” (e.g., termination delay, driver delay) may be a source of delay in the reading or writing of data. The termination delay is connected to a terminator that is utilized to electrically condition a bus to eliminate ringing. The driver enable delay is connected to the enable pin on the IP. This controls exactly when the memory interface device drives data on the bus during writes. The driver delay is utilized to delay when a signal (a data or data strobe signal) is driven or written, from the MID 404 to the data bus. The receiver delay may be utilized to perform the PBD described previously. The receiver enable delay may be utilized to eliminate receiver ringing when data is not being driven on the bus. The ringing occurs when the data bus is not being driven by either device. In this case the bus voltage goes to the VDD/2 level, which is exactly what the receiver threshold is. Any small variation on the bus can cause wild oscillations on the output of the comparator; therefore we ignore the bus unless reading. To summarize, the receiver gate is disabled when the memory device is driving data and the receiver gate when no data is being driven by the memory device. By utilizing exemplary embodiments of the present invention, all of these delays are uniquely programmable (for each data bit and data strobe).

In an exemplary embodiment of the present invention, the data pin logic circuitry 502 (one per data bit) and data strobe pin logic circuitry 504 (one per data strobe) are included in the MID 404. The MID 404 acts as an interface between the busses in the memory system (i.e., data and control) and the memory device 402. As described previously, the MID 404 uses the delay blocks depicted in FIG. 5 to increase the window available for data sampling across one or more data bits.

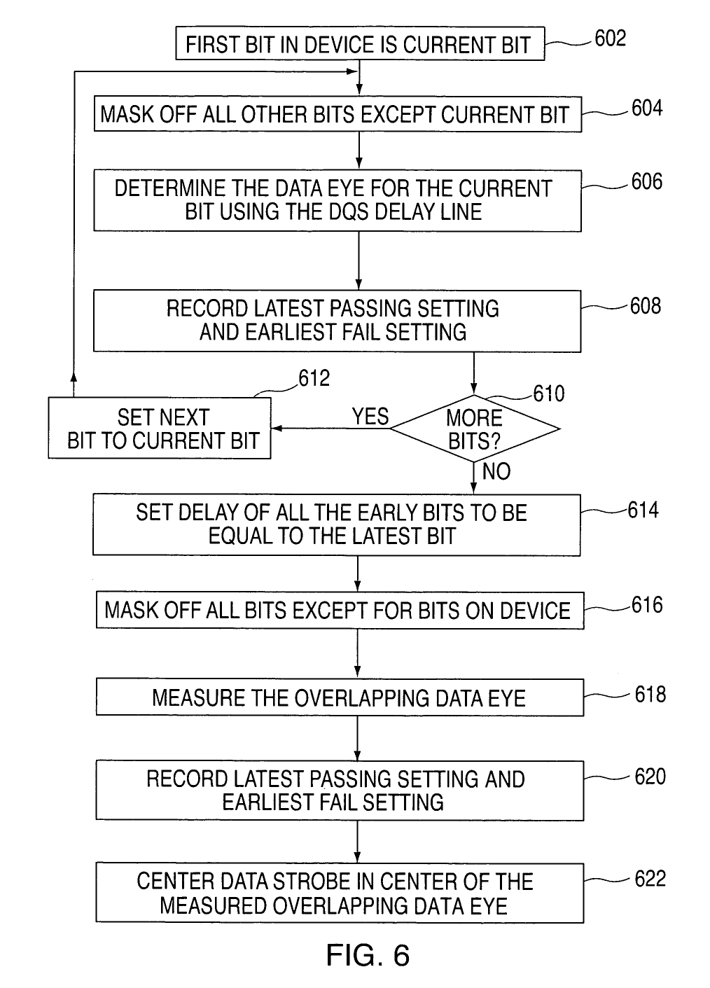

FIG. 6 depicts a process flow diagram for correcting error terms in accordance with exemplary embodiments of the present invention. The idea is to write a training pattern into a specific address in the memory device 402 and to perform PBD and DSC to sample data at a desired frequency and to calibrate the read data on a per pin basis. This is accomplished by using a software algorithm using firmware commands or a hardware state machine memory controller in the MID 404 to write the background pattern and then to perform the necessary memory device 402 driver adjusts, reads and refreshes to calibrate a read data path for the memory interface.

The process depicted in FIG. 6 is performed for each memory device 402 in the memory system. At step 602, the current bit is set to the first bit in the device. At step 604, all bits except for the current bit are masked off. At step 606, the data eye for the current bit is determined using the data strobe delay line. This may be done by performing a Schmoo test on the data eye for the current bit using the data strobe delay line. As used herein a “Schmoo test” refers to a means of varying one parameter while keeping all other parameters constant, and recording a pass or fail value for each setting of the varied parameter. At step 608, the latest passing setting and earliest fail setting is recorded for the current bit. At step 610, it is determined if there are more bits. If there are more bits, then the next bit is set to the current bit at step 612 and processing continues at step 604. If there are no more bits, then step 614 is performed.

At step 614, the delay of all the early bits is set to be equal to the latest bit (may be process compensated or raw number of elements). All bits except for bits on the memory device 402 are masked off at step 616. At step 618, the overlapping data eye is measured (e.g., by performing a Schmoo test and varying the data strobe). At step 620, the latest passing setting and earliest fail setting are recorded and at step 622, the data strobe is centered in the center of the measured overlapping data eye. After the process depicted in FIG. 6 is completed for each device within the memory system, other control delays (e.g., the termination delay) may be manually programmed to safely surround algorithm generated delay settings. The automated process depicted in FIG. 6 may be executed at power-on to create a machine specific set of listing.

DDR2 DRAMs support variable pull-up/pull down (PU/PD) drivers and these knobs, along with the memory interfaces sub-cycle delay knobs may be utilized to find the correct settings for each DRAM memory device 402. Using the information delay information obtained by the algorithm depicted in FIG. 6, all the data bits are delayed to the latest known passing setting (can be process compensated, or a number of delay steps). Then, the data strobe is delayed to be centered in the latest arriving setting window equal to: [{(latest_known_fail_to_pass)−(earliest_known_pass_to_fail)}/2].

For the current PU/PD setting, the data eye is equal to: {(latest_known_fail_to_pass)−(earliest_known_pass_to_fail)}. The algorithm will save the maximum overlapping data eye value and PU/PD setting for which it occurred, and then select the PU/PD setting with the largest eye and set the DRAM memory device 402 to that setting. This algorithm is run for every device in the memory array. Exemplary embodiments of the present invention may utilize an alternative method that includes saving the eye settings for each pass and then pick the best PU/PD setting. This alternative method does not need a final pass of the DSC/PBD. The method outlined here assumes that we only saved the best setting. Note, that each time the PBD and DSC is executed, the PBD and DSC results of the previous run are lost. Therefore, a final pass of PBD and DSC must be run for the selected PU/PD setting the DRAM memory device 402. Finally, PBD is executed for a device going to all ranks without changing the PU/PD of the device. As used herein the term “rank” refers to the set of memory devices 402 that are accessed during a single memory transfer. The number of memory devices 402 accessed is equal to the size of the data bus divided by the width of the memory device 402. A single chip select line is common for all devices in a single rank. Advantages to utilizing a hardware state machine to perform automatic read calibration include that the process is automated, that the process can be executed at power on to create a machine specific list of settings, that the hardware assisted state machine reduces initial program load (IPL) time (versus a software implementation) and that it can be tailored to individual devices.

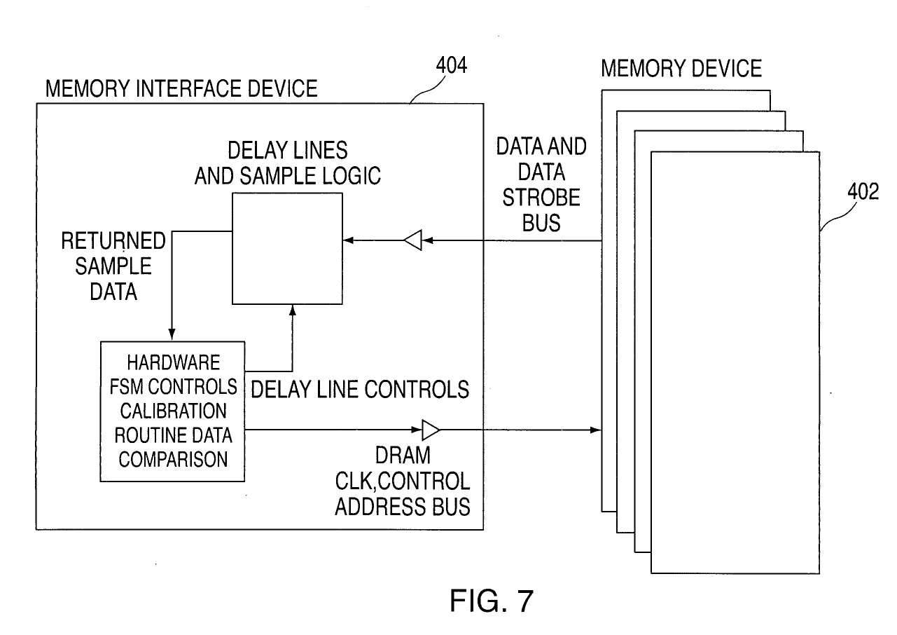

FIG. 7 depicts a hardware assisted calibration block diagram that may be implemented to correct error terms in accordance with exemplary embodiments of the present invention. FIG. 7 depicts the MID 404 receiving data on a data bus from the memory device 402 and data strobe input on a data strobe bus from the memory device 402. The MID 404 includes a delay lines and sampling logic block and a hardware finite state machine (FSM) block. The delay lines and sampling logic block receives the data and the data strobe from the memory device 402 along with delay line controls from the FSM block. The delay lines and sampling logic block transmits returned sample data to the hardware FSM block. The hardware FSM block controls the calibration routine and performs data comparison. Based on the returned sample data, the hardware FSM block outputs delay line controls to the delay lines and sample logic block. The hardware FSM outputs a DRAM clock, as well as control data to the control bus and address data to the address bus for input to the memory device 402.

An exemplary embodiment of a hardware algorithm to perform automatic read calibration follows.

For each rank:

```
For each device in the rank
  For each PU/PD combination of driver impedance settings
    For each bit in device
        Mask off all other bits except current
        Schmoo the data eye for a single bit using the data strobe
        delay line
        Record latest passing setting and earliest fail setting
      End for each bit in device
      Set delay of all the early bits to equal latest bit
      Mask off all bits except for bits on device
      Measure the overlapping data eye by Schmooing the data
      strobe delay line
      Record latest passing setting and earliest fail setting
      Record overlapping data eye for PU/PD setting
    End for each PU/PD combination of driver impedance settings
    Select best PU/PD setting
    Mask off all bits except for bits on device
    Measure the overlapping data eye by Schmooing the data strobe
    Record latest passing setting and earliest fail setting
    Center the data strobe in the center of the measured overlapping
    data eye
  End for each device in the rank
End for each rank
```

An exemplary embodiment of the present invention includes a procedure to automatically calibrate a write delay to more closely align write bits that are strobed by the same clock. The procedure to calibrate the write to memory assumes that the memory reads have been calibrated prior to calibrating the write data. To calibrate the write data, the algorithm will perform a similar PBD calibration procedure as discussed previously, however, this time write commands are followed by read commands to see if the data was properly stored in the array. The PU/PD settings are not modified as they were optimized via the read calibration.

An exemplary embodiment of an algorithm to perform automatic write calibration follows.

For each rank:

```
      For each device in the rank
        For each bit in device
          For read data comparison, mask off all other
          bits except current
Schmoo the data eye for a single bit using the write data strobe delay line
            (Schmoo is performed by issuing a write to memory with a
            known data pattern and then reading it back with the
            optimized read settings)
          Record latest passing setting and earliest fail setting
        End for each bit in device
        Set write delay of all the early bits to equal latest bit
        For read data comparison, mask off all bits except for bits
        on device
        Measure the overlapping data eye by Schmooing the write
        data strobe
          (Schmoo is performed by issuing a write to memory with a
          known data patterns and then reading it back with
          the optimized settings)
        Record latest passing setting and earliest fail setting
        Record overlapping data eye
        Center the write data strobe in the center of the measured
        overlapping data eye
      End for each device in the rank
End for each rank
```

Once the above procedure is completed, the read and write will be calibrated on the memory interface. This calibration requires that both the drive and receive pins of the memory data and memory data strobes have a delay line connected such that signals can be delayed and optimized. In an exemplary embodiment of the present invention, the setting of the delay lines in the above algorithm is controlled by the internal hardware FSM.

The programmable delay solution implemented by exemplary embodiments of the present invention includes a delay chain that supports a programmable setting for each bit and strobe within a memory system to support a memory system in which the card wiring may be sub-optimal. In addition, each of the control lines (e.g., receiver gate, tri-state and device termination) of the memory device I/O have programmable delays as well. The receiver gate is an I/O control that forces the comparator output on the I/O to a DC value when enabled. When disabled, it allows the comparator to pass the input to output with normal characteristics. The tristate control pin is an I/O control that when enabled allows the I/O to drive a value on the bus, and when disabled causes the I/O to output a high-Z impedance. Device termination is another I/O control that when enabled causes an extra resistance to be enabled on the bidirectional net to eliminate ringing.

Exemplary embodiments of the present invention may be utilized to improve the overlapping data eye during writes and reads, therefore providing noise immunity at slower frequencies and a higher potential frequency of operation. The margin of error may be reduced down to the smallest programmable setting plus any jitter plus any noise. In addition, exemplary embodiments of the present invention may also provide better bus turn around time by controlling very precisely the time when the bus is driven and tri-stated.

As described above, the embodiments of the invention may be embodied in the form of computer-implemented processes and apparatuses for practicing those processes. Embodiments of the invention may also be embodied in the form of computer program code containing instructions embodied in tangible media, such as floppy diskettes, CD-ROMs, hard drives, or any other computer-readable storage medium, wherein, when the computer program code is loaded into and executed by a computer, the computer becomes an apparatus for practicing the invention. The present invention can also be embodied in the form of computer program code, for example, whether stored in a storage medium, loaded into and/or executed by a computer, or transmitted over some transmission medium, such as over electrical wiring or cabling, through fiber optics, or via electromagnetic radiation, wherein, when the computer program code is loaded into and executed by a computer, the computer becomes an apparatus for practicing the invention. When implemented on a general-purpose microprocessor, the computer program code segments configure the microprocessor to create specific logic circuits.

While the invention has been described with reference to exemplary embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims. Moreover, the use of the terms first, second, etc. do not denote any order or importance, but rather the terms first, second, etc. are used to distinguish one element from another.

1. A memory system comprising:
a plurality of delay lines in communication with a bus attached to a memory device, wherein the bus includes a plurality of wires and each of the delay lines corresponds to one of the plurality of wires; and
a processor in communication with the delay lines for:
receiving a plurality of data bits and a data strobe via the wires on the bus, wherein each of the data bits includes a data eye;
automatically calibrating a target data eye for the data bits;
adjusting the delay lines so that the data eye of each of the data bits corresponds to the target data eye; and
centering the data strobe over the target data eye.

2. The system of claim 1 wherein the automatically calibrating includes selecting a latest arriving bit from the plurality of bits and using the data eye of the latest arriving data bit as the target data eye.

3. The system of claim 1 wherein the plurality of data bits are read data bits and the data strobe is a read data strobe.

4. The system of claim 1 wherein the plurality of data bits are write data bits and the data strobe is a write data strobe.

5. The system of claim 1 wherein the instructions are implemented by circuitry.

6. The system of claim 1 wherein the instructions are implemented by software.

7. The system of claim 1 wherein the instructions are implemented by a combination of circuitry and software.

8. The system of claim 1 wherein the delay lines are multiplexor chains.

9. A method for providing programmable delay chains in a memory system, the method comprising:
receiving a plurality of data bits and a data strobe via wires on a bus, wherein each of the data bits includes a data eye, and the memory system includes a plurality of delay lines in communication with the wires on the bus; and
automatically calibrating a target data eye for the data bits;
adjusting the delay lines so that the data eye of each of the data bits corresponds to the target data eye; and
centering the data strobe over the target data eye.

10. The method of claim 9 wherein the automatically calibrating includes selecting a latest arriving bit from the plurality of bits and using the data eye of the latest arriving data bit as the target data eye.

11. The method of claim 9 wherein the plurality of data bits are read data bits and the data strobe is a read data strobe.

12. The method of claim 9 wherein the plurality of data bits are write data bits and the data strobe is a write data strobe.

13. The method of claim 9 wherein the instructions are implemented by circuitry.

14. The method of claim 9 wherein the instructions are implemented by software.

15. The method of claim 9 wherein the instructions are implemented by a combination of circuitry and software.

16. The method of claim 9 wherein the delay lines are multiplexor chains.

17. A storage medium encoded with machine readable computer program code for providing programmable delay chains in a memory system, the storage medium including instructions for causing a computer to implement a method comprising:
receiving a plurality of data bits and a data strobe via wires on a bus, wherein each of the data bits includes a data eye, the memory system includes a plurality of delay lines in communication with the wires on the bus; and
automatically calibrating a target data eye for the data bits;
adjusting the delay lines so that the data eye of each of the data bits corresponds to the target data eye; and
centering the data strobe over the target data eye.
